(19) United States
(12) Patent Application Publication
(10) Pub. No.: US 2026/0096015 A1
(43) Pub. Date: Apr. 2, 2026

(54) PCB ROUTING TOPOLOGY OF M-LVDS WITH FILTERS

(71) Applicant: Raytheon Company, Tewksbury, MA (US)

(72) Inventors: Thanh T. Tran, HOUSTON, TX (US); Glenn D. Henseler, PLANO, TX (US); Christopher T. Yates, II, PALM HARBOR, FL (US); Joseph A. Kendricks, PLANO, TX (US)

(21) Appl. No.: 18/899,507

(22) Filed: Sep. 27, 2024

(51) Int. Cl. H05K 1/02; H04L 25/02

(52) U.S. Cl. CPC H05K 1/0245; H04L 25/0272; H05K 1/025; H05K 2201/1006

(57) ABSTRACT

Circuitry and method are described for enabling multiple loads on a differential low voltage differential signaling pair (M-LVDS). A printed circuit board (PCB) contains a M-LVDS driver and leads that route a main channel that carries a differential signal from the driver to an area in which loads are populated. The main channel is split into branches that contain application-specific integrated circuits (ASICs) as the loads. The branches have the same characteristic impedance as the main channel. Filters are disposed in each branch and are coupled between the driver and the ASICs. Each filter is a first order or higher filter. Fewer filters than ASICs are on each branch, with the filters being disposed between the driver and ASICs closest to the driver (with smaller propagation delay). The filters are configured differently at each ASIC input to compensate for the delay.

### TECHNICAL FIELD

The present subject matter relates generally to multipoint low voltage differential signaling (M-LVDS) and more specifically to printed circuit boards (PCBs) that mitigate deficiencies in M-LVDS.

### BACKGROUND

Low voltage differential signaling (LVDS) and multipoint LVDS (M-LVDS) are widely used standards for high-speed data communication in various electronic applications. However, as the demand for increased functionality and integration grows, designers face challenges in implementing these standards with multiple loads on a single channel in a PCB. Traditional approaches often result in signal integrity issues and timing violations when multiple loads are connected to a single bus, limiting the scalability and performance of electronic systems.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1 illustrates a PCB stack according to some embodiments.

FIG. 2A illustrates a PCB stack and associated circuitry in accordance with some aspects.

FIG. 2B illustrates an extended PCB stack of FIG. 2A and signaling in accordance with some aspects.

FIG. 3A illustrates a digital waveform in the time domain according to some embodiments.

FIG. 3B illustrates a digital waveform in the frequency domain according to some embodiments.

FIG. 3C illustrates a single pole lowpass filter according to some embodiments.

FIG. 4A illustrates a circuit diagram to a first load according to some embodiments.

FIG. 4B illustrates a circuit diagram to a second load according to some embodiments.

FIG. 4C illustrates a circuit diagram to a third load according to some embodiments.

FIG. 4D illustrates a circuit diagram to a fourth load according to some embodiments.

FIGS. 5A and 5B illustrate a circuit diagram according to some embodiments.

FIG. 6 illustrates a block diagram of an electronic device in accordance with some aspects.

FIG. 7 illustrates a method of providing a differential signal in a PCB in accordance with some aspects.

### DETAILED DESCRIPTION

A PCB is described that uses routing topology for M-LVDS to enable multiple loads on a single differential channel while maintaining signal integrity and minimizing timing violations. The design compensates for the signal skew associated multiple loads on a single M-LVDS channel. The main channel is routed to an area of the PCB in which the loads are populated. The main channel is split into multiple branches (PCB traces) that have the same characteristic impedance as the main channel. A filter is provided at each of the load inputs of a closest subset of the loads in each branch (i.e., loads that have the shortest propagation delay between the M-LVDS driver and load), that is, the number of filters on each branch is less than the number of loads—fewer filters than loads are on each branch. The filters are configured differently at each input to compensate for the delay at the load and to optimize signal integrity. The design allows the PCB layer stack to be identical for different branches.

M-LVDS is a standard for communicating at high speed in multi-point applications using differential signaling, in which receivers detect data based on the voltage difference between two complementary electrical signals. M-LVDS applications are used for low power, high speed (about 100-200 Mbps), and moderate distance (about 20-40 meters) data transfer. Typical applications use PCB traces or short wired/backplane links. The communications may be one-way (multi-drop receivers) or two-way (half-duplex or full duplex transceivers) and the devices may be either Type 1 or Type 2. The differential voltage on a terminated bus when no device is transmitting is close to 0 V for Type 1 M-LVDS receivers, while Type 2 M-LVDS receivers have an offset input threshold of about +50 mV to about +150 mV to avoid undefined outputs for a standard receiver with symmetrical input thresholds. A single clock source may be used to drive the M-LVDS devices using an LVDS buffer acting as a fan-out device.

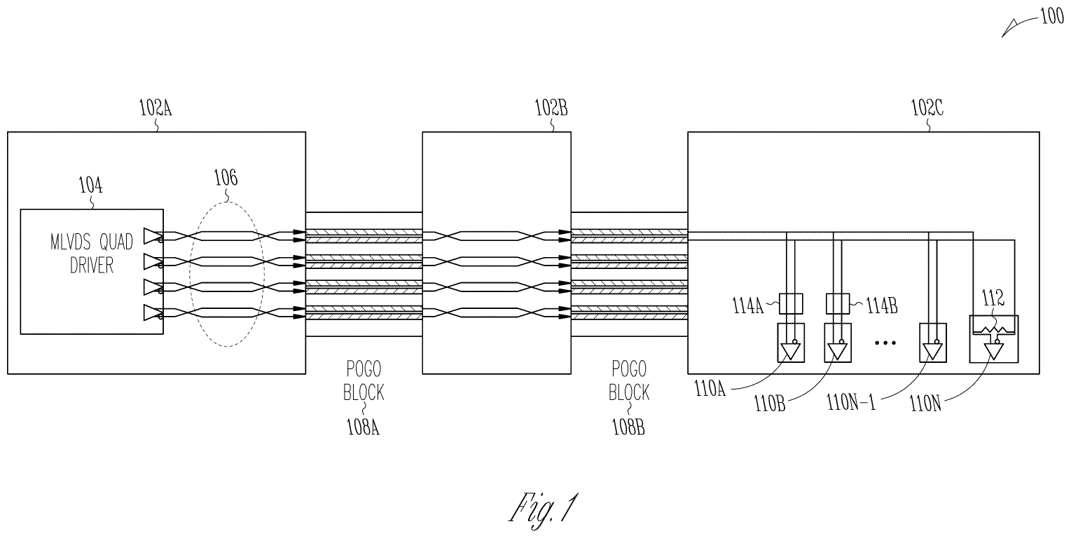

FIG. 1 illustrates a PCB stack according to some embodiments. The PCB stack 100 may include a number of circuit card assemblies (CCAs) 102a, 102b, 102c that are individual PCBs having different circuitry and connected by a channel (also referred to as a bus) that carries multiple differential signals each using a different pair of striplines or microstrips. Each CCA 102a, 102b, 102c may be formed from a PCB material such as a Polymide/FR4 board.

The Sub-C CCA 102a may contain a M-LVDS driver 104 configured to provide multiple differential signals 106 along microstrips. The microstrips may have a differential characteristic impedance of, for example, about 100Ω. The differential signals 106 shown in FIG. 1 may include clock signals, data signals, transmit/receive (T/R) signals, and analog output (AO) signals, although other signals may be present dependent on the type of M-LVDS driver 104.

The second CCA 102b may act as a pass through and may have differential striplines whose characteristic impedances match those of the microstrips of first CCA 102a (e.g., about 100Ω). The second CCA 102b may be electrically coupled to the first CCA 102a through electrical connections such as a pogo block connector 108a containing pogo pins, which are spring-loaded connectors designed for high-reliability connections between circuit elements or CCAs/PCBs. Each pogo pin may be formed from Copper (Cu) and have an Equivalent Series Resistance (ESR) of, for example, 0.070Ω per pin. Each pogo pin may provide a different path for each of the differential signals 106.

The third CCA 102c may have differential striplines whose characteristic impedances match those of the second CCA 102b (e.g., about 100Ω). The third CCA 102c may be electrically coupled to the second CCA 102b through another pogo block connector 108b containing multiple polo pins. The third CCA 102c may contain multiple loads 110a-110n, such as application-specific integrated circuits (ASICs). In some embodiments, only the final load 110n has a termination resistor 112 in parallel with inputs of the final load 110n. Other circuit elements, such as filters 114a, 114b, may be coupled between several of the loads 110a, 110b and the M-LVDS driver 104.

The lengths of the differential signal paths may be different in each circuit element. For example, the differential signal paths on the first CCA 102a may be around 1 inch, the length of the first pogo block connector 108a may be about 1.2 inches, the differential signal paths on the second CCA 102b may be less than 2 inches, the length of the pogo pins of the second pogo block connector 108b may be about 0.2 inches, and the differential signal paths on the first CCA 102a may be between about 0.5 inches for the path to the first load 110a and about 10 inches for the final load 110n.

However, when multiple loads are coupled to a single channel (or bus), excessive loading may cause timing violations and signal integrity issues may result. For example, when 16 application-specific integrated circuits (ASICs) are used as the loads 110a-110n without the additional filters 114a, 114b being present using the typical signal lengths described, a 907 mV differential peak-to-peak 100 MHz signal may occur at the first load 110a, which is reduced to a 78 mV differential peak-to-peak 100 MHz signal at the final load 110n. However, as the minimum valid peak-to-peak LVDS voltage is 100 mV, this results in a voltage violation at the final load 110n.

To increase the number of loads able to be driven using the PCB, another M-LVDS driver and bus may be added to reduce the number of loads on each bus. The use of separate busses, however, may cause issues related to timing among the loads in the different buses, and thus may involve extensive simulations and controlled device layout to compensate for the timing errors.

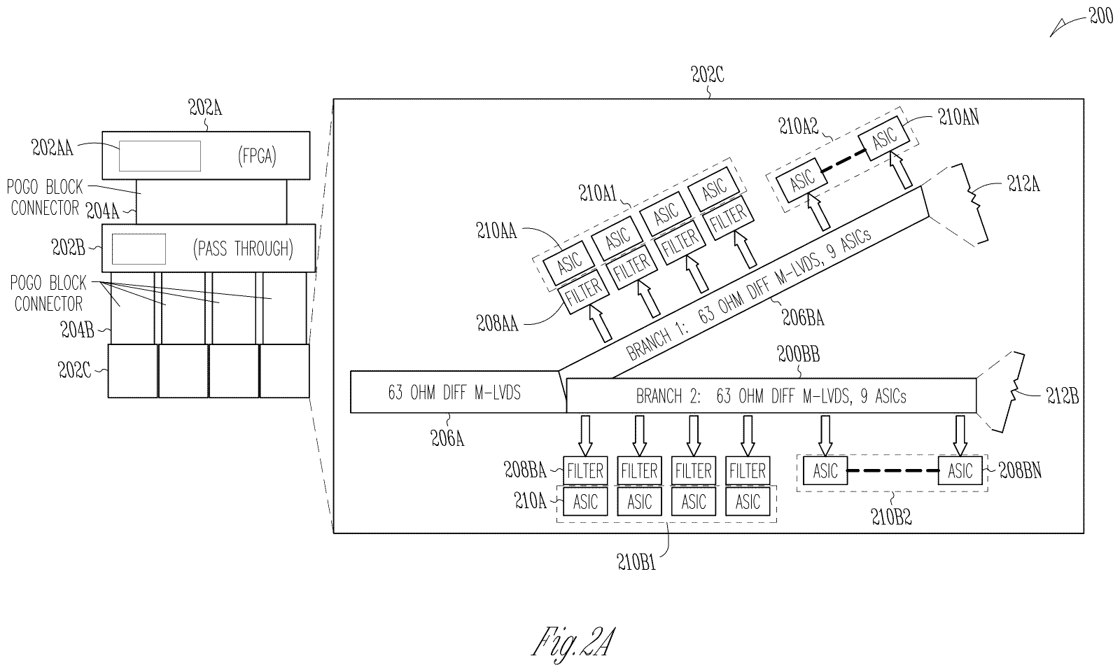

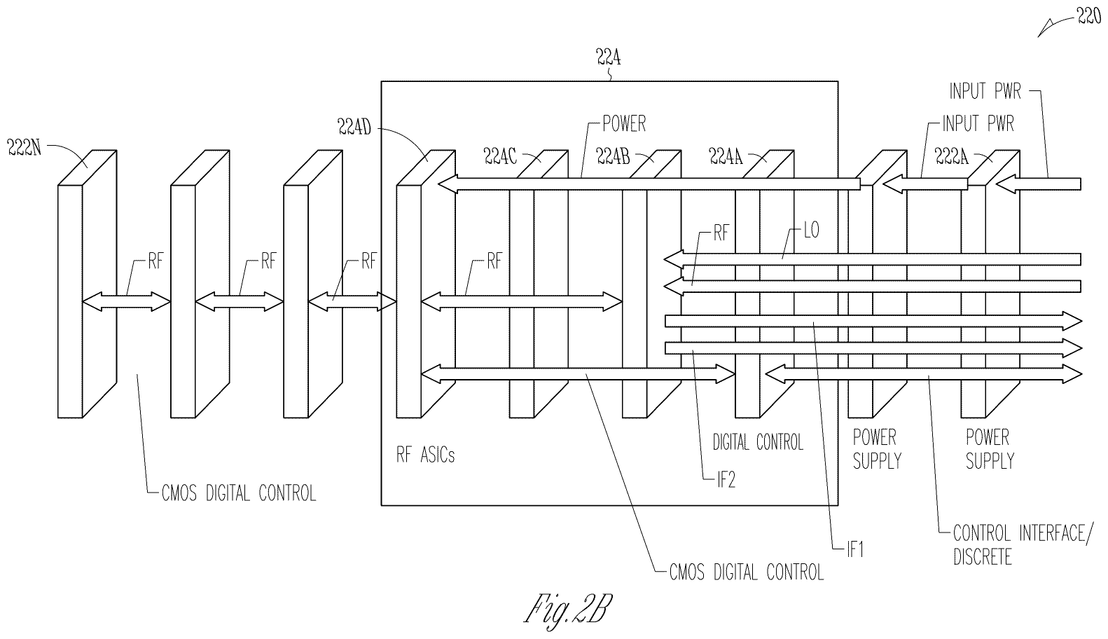

FIG. 2A illustrates a PCB stack and associated circuitry in accordance with some aspects. The PCB stack 200 may include first CCA 202a, second CCA 202b, and one or more third CCAs 202c having different circuitry and connected by a single channel that carries multiple differential signals. Each of first CCA 202a, second CCA 202b, and third CCAs 202c may be formed from a PCB material such as a Polymide/FR4 board. The first CCA 202a may include a floating point gate array (FPGA) that contains a M-LVDS driver 202aa configured to provide multiple differential signals to loads 208aa-208an, 208ba-208bn in third CCAs 202c. The first CCA 202a may be electrically coupled to second CCA 202b through a pogo block connector 204a; second CCA 202b may be electrically coupled to each third CCAs 202c through a different second pogo block connector 204b.

The third CCA 202c may contain a single channel 206a that has a particular differential characteristic impedance (shown as 63Ω). The single channel 206a may carry the differential signals from the M-LVDS driver 202aa. The single channel 206a may be split into n linear branches 206ba, 206bb (which may be limited, as shown in FIG. 2A, to 2 branches). Each branch 206ba, 206bb may have the same characteristic impedance as the single channel 206a and may be terminated by a respective resistor 212a, 212b that provides the same characteristic impedance (although other termination techniques may be used instead to provide the same impedance). The use of the same characteristic impedance in each branch 206ba, 206bb and the same as the single channel 206a, as well as the use of a single channel 206a throughout the PCB stack 200 outside of the third CCA 202c, enables the use of high-density PCB designs, where changing the PCB stack is not practical due to space constraints as well as formation of narrow traces to produce high characteristic impedance.

Each branch 206ba, 206bb may contain multiple loads 210aa-210an, 210ba-210bn, such as application-specific integrated circuits (ASICs). The differential signals from the M-LVDS driver 202aa are thus routed to the physical area in which the loads 210aa-210an, 210ba-210bn are located. Each load 210aa-210an, 210ba-210bn may be the same. Each branch 206ba, 206bb may contain the same number of loads 210aa-210an, 210ba-210bn. In each branch 206ba, 206bb, a first set of the loads 210a1, 210b1 may have inputs coupled to the respective branch 206ba, 206bb (and thus receive the differential signals from the M-LVDS driver 202aa) through a different filter 208aa, 208ba. The first set of the loads 210a1, 210b1 may be the loads 210aa-210an, 210ba-210bn most electrically proximate to the M-LVDS driver 202aa; in other words, the signals from the M-LVDS driver 202aa arriving at the first set of the loads 210a1, 210b1 may have the least propagation delay among the signals from the M-LVDS driver 202aa arriving at all of the loads 210aa-210an, 210ba-210bn. The propagation delay is a function of the square root of the total lumped parasitic inductance and total lumped parasitic capacitance and is thus directly proportional to the length traveled by the differential signal (single channel length+length of portion of branch to the particular load).

A second set of the loads 210a2, 210b2 may have inputs coupled to the respective branch 206ba, 206bb directly without the filters 208aa, 208ba used in conjunction with the first set of the loads 210a1, 210b1. The number of loads 210aa-210an, 210ba-210bn in the first set of the loads 210a1, 210b1 may be the same in each branch 206ba, 206bb. Similarly, the number of loads 210aa-210an, 210ba-210bn in the second set of the loads 210a2, 210b2 may be the same in each branch 206ba, 206bb. The number of loads 210aa-210an, 210ba-210bn in the first set of the loads 210a1, 210b1 may be the same as or may be different from the number of loads 210aa-210an, 210ba-210bn in the second set of the loads 210a2, 210b2 in each branch 206ba, 206bb. FIG. 2A shows an example in which there are 18 ASICs, 9 ASICs on each branch 206ba, 206bb, and in which the closest four ASICs form the first set of the loads 210al, 210b1. The number of loads 210aa-210an, 210ba-210bn, however, and number of branches 206ba, 206bb may vary dependent on the topology and design.

Each filter 208aa, 208ba may include a single pole lowpass filter. However, each filter 208aa, 208ba along a particular branch 206ba, 206bb may be configured differently to compensate for the delay and to optimize signal integrity. The filter design addresses the transmission line effects that cause each load 210aa-210an, 210ba-210bn of the first set of the loads 210a1, 210b1 on the respective branch 206ba, 206bb to have the lowest propagation delays. Accordingly, even though the filters 208aa, 208ba may have the same general design (single pole lowpass filter), the characteristics of the filters 208aa, 208ba differ, dependent on the load 210aa-210an, 210ba-210bn to which the filter 208aa, 208ba is coupled. The use of the filters 208aa, 208ba allows the delay at the first set of the loads 210a1, 210b1 to substantially match that of the other loads 210aa-210an, 210ba-210bn. The filters 208aa, 208ba added are scaled to appear to the circuitry like high impedance stubs to minimize transmission line effects. Note that other filter designs may be applied and/or additional filters may be used but are not described for convenience. In this design, the reflections caused by characteristic impedance mismatch are filtered at the input of each load 210aa-210an, 210ba-210bn of the first set of the loads 210a1, 210b1 on the respective branch 206ba. Each filter 208aa, 208ba is tuned differently, the filter closest to the M-LVDS driver 202aa (and split of the single channel 206a) having more reflections than other filters on the respective branch 206ba, leading to the −3 dB filter being set to a lower corner frequency.

FIG. 2B illustrates an extended PCB stack of FIG. 2A and signaling in accordance with some aspects. The extended PCB stack 220 includes multiple PCBs 222a-222n, including the PCB stack 224 of FIG. 2A. The PCB stack 224 shows the first CCA 224a, an intermediary PCB 224b, the second CCA 224c, and the third CCA 224d described above. The first CCA 224a provides digital control in the extended PCB stack 220 and interfaces with the radio frequency (RF) ASICs on the third CCA 224d through pogo pins. As shown, the signaling includes power (PWR) supplied to each of the PCBs 222a-222n from an external power supply. The external power may be modified (e.g., filtered, adjusted to one or more voltages) and routed through one or more external-facing PCBs, such as initial PCB 222a, to the remaining PCBs. The signaling also includes control signals (both interface and discrete signals) supplied to the first CCA 224a, and local oscillator (LO) signals to downconvert analog signals to baseband, RF signals, and multiple sets of intermediate frequency (IF) signals (IF1, IF2), at least some of which may originate or terminate at the intermediary PCB 224b. The RF signals may be received at the last PCB 222n and supplied to the intermediary PCB 224b. CMOS digital control signals provided between the first CCA 224a and the third CCA 224d may be used to control the ASICs (and other circuitry) on the third CCA 224d.

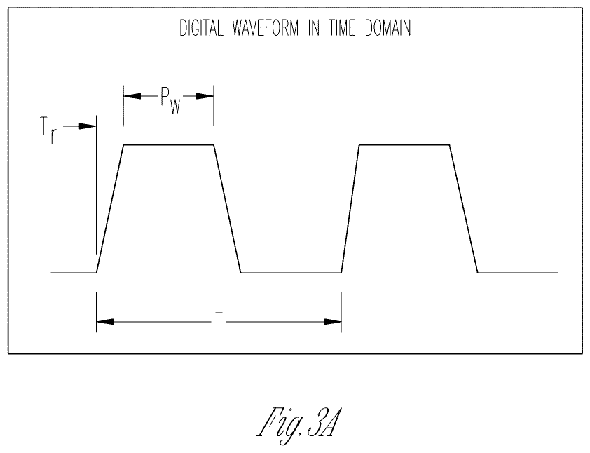

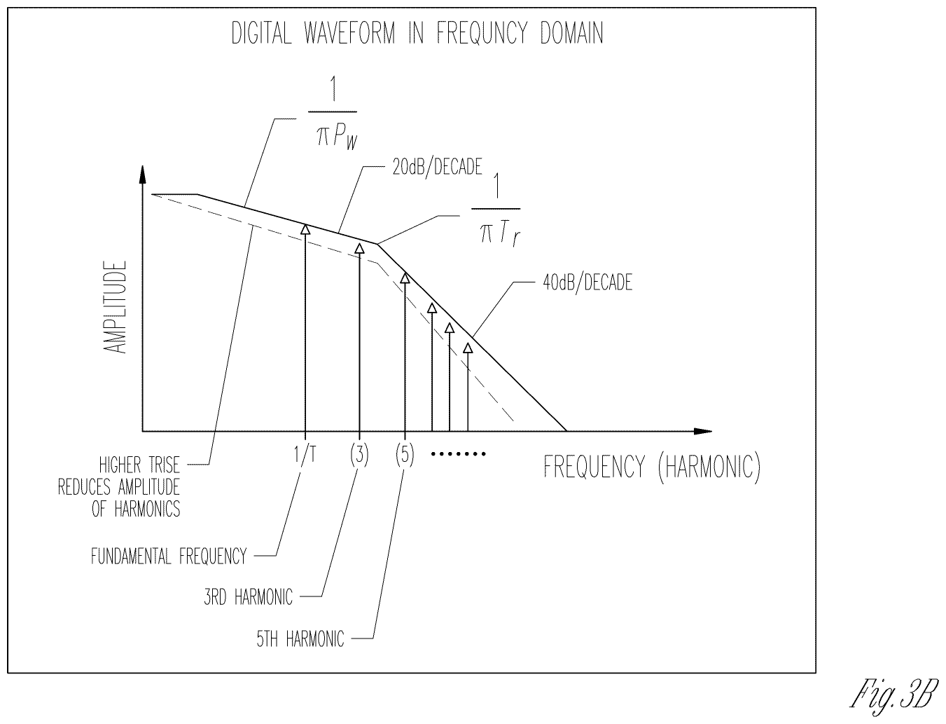

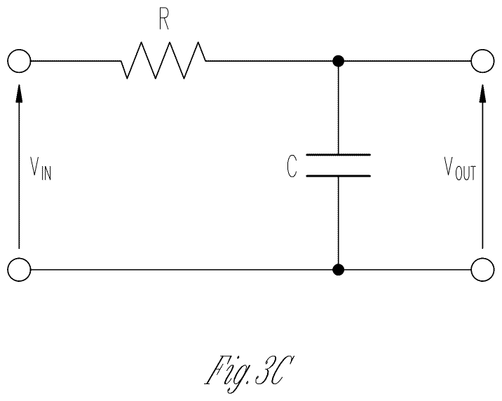

FIG. 3A illustrates a digital waveform in the time domain according to some embodiments. The time domain digital waveform has a periodicity T, a pulse width Pw, and a rise time Tr. The x-axis in the graph of the time domain digital waveform is time and the y-axis is amplitude. FIG. 3B illustrates a digital waveform in the frequency domain according to some embodiments. The time domain characteristics of the digital waveform are mirrored in the frequency domain. The x-axis in the graph of the frequency domain digital waveform is frequency and the y-axis is amplitude. As shown, the fundamental frequency of the frequency domain digital waveform is at 1/T. The harmonic amplitudes are inversely proportional to Tr, with harmonic amplitude decreasing at 20 db/decade until 1/(πTr) and then at 40 db/decade (in FIG. 3B, this occurs between the 3^{rd} harmonic and the 5^{th} harmonic).

In particular, to compensate for the delay and improve signal integrity, in the system design shown in FIG. 2A, a single pole lowpass filter is implemented at each of the first four ASICs. Each filter has a different corner frequency to reduce the energy of the harmonics of the signal impinging on the filter to slow down the edge rate, thereby reducing 1/(πTr). Simulations were used to determine that filters coupled to loads other than the first four loads closest to the M-LVDS driver did not appreciably improve signal integrity because these loads were closer to the termination resistor at the end of the branch. Each of the two branches in FIG. 2A has a 63 ohm characteristic impedance and a 63 ohm termination resistor (resistor 212a and resistor 212b). The ASICs (ASIC 210a2 and ASIC 210b2) sitting closer to the matched termination resistors (resistor 212a and resistor 212b) have less transmission line effect which leads to better signal integrity. The characteristic impedance, Zo, of a conductor is equal to:

$${Z}_{0} = \sqrt{L / C} ,$$

where L is an equivalent inductance and C is an equivalent capacitance of one conductor. The single-ended characteristic impedance is equal to Z₀ while the differential characteristic impedance is 2Z₀.

FIG. 3C illustrates a single pole lowpass filter according to some embodiments. One or more of the filter characteristics may vary between adjacent filters. In the example provided herein, for the first filter (coupled to the first ASIC, closest to the driver), for a channel characteristic impedance of 63Ω, the filter has R=128Ω and C=5 pF, giving a corner frequency of about 249 MHz, the 3^{rd} harmonic of 100 MHz is 300 MHz. For the second filter (coupled to the second ASIC, which is the next closest ASIC to the driver after the first ASIC), the filter has R=64Ω and C=5 pF, giving a corner frequency of about 497 MHz, the 5^{th} harmonic of 100 MHz is 500 MHz. For the third filter (coupled to the third ASIC, which is the next closest ASIC to the driver after the second ASIC), the filter has R=32Ω and C=3 pF, giving a corner frequency of about 1.66 GHz. For the fourth filter (coupled to the fourth ASIC, which is the next closest ASIC to the driver after the third ASIC), the filter has R=16Ω and C=3 pF, giving a corner frequency of about 3.3 GHz. As shown, while the resistances of the adjacent filters continually decrease (by ½) with increasing distance from the driver, the capacitances of the adjacent filters either remained the same or decreased (alternating between remaining constant and being reduced).

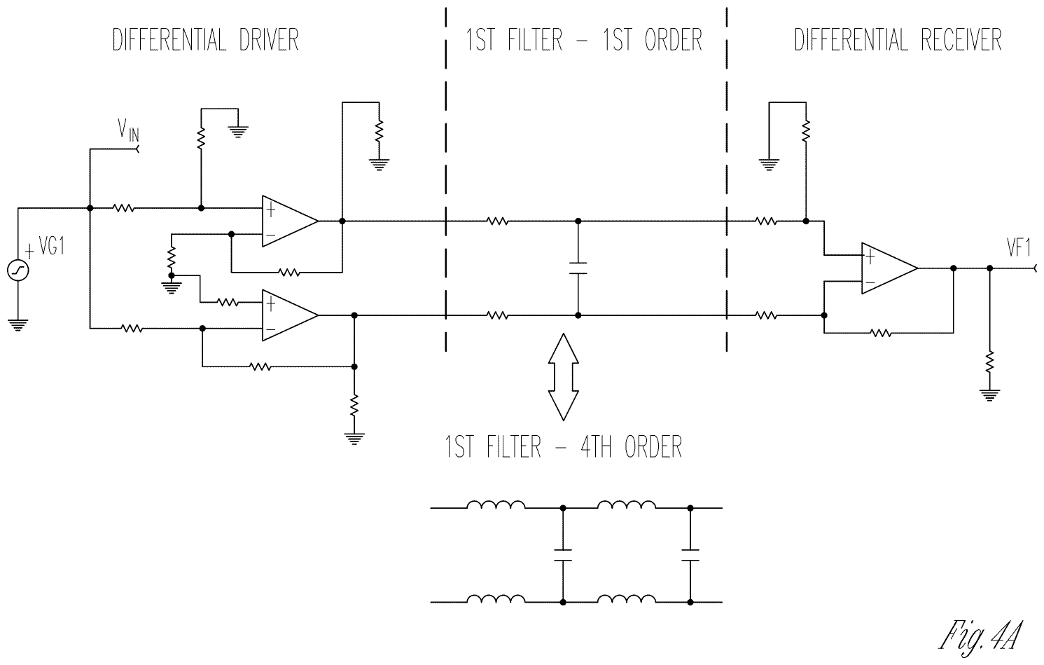

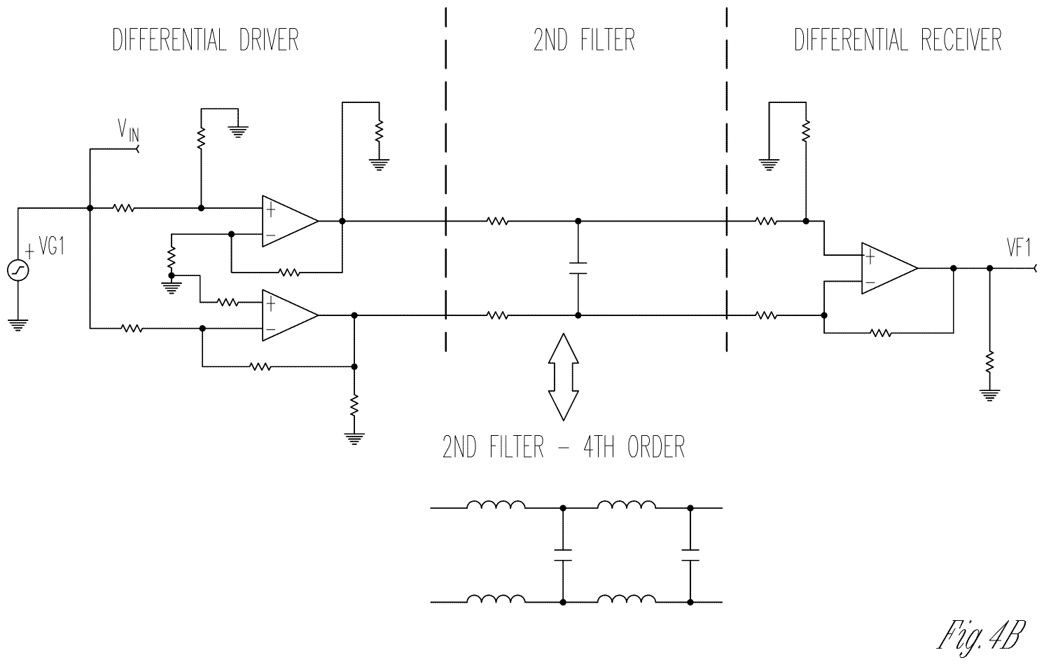

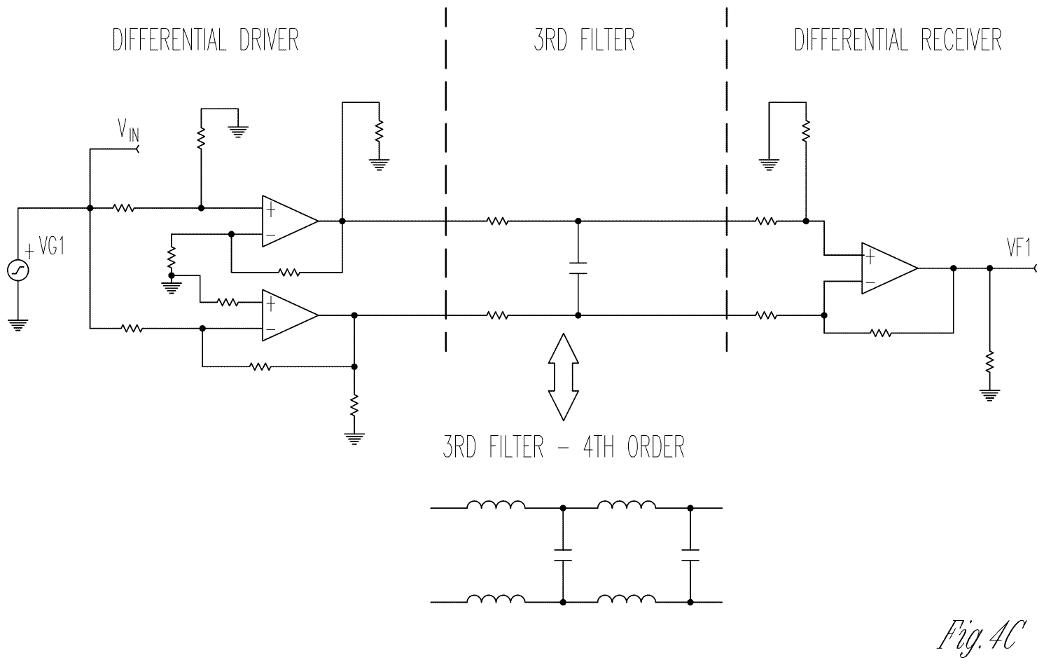

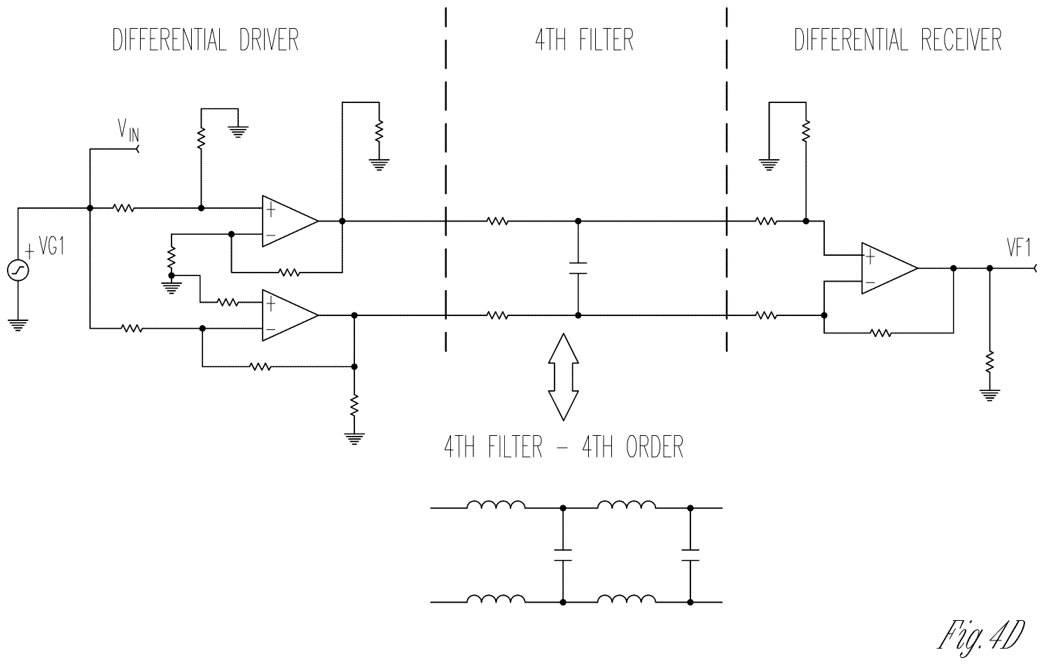

FIG. 4A illustrates a circuit diagram to a first load according to some embodiments. FIG. 4B illustrates a circuit diagram to a second load according to some embodiments. FIG. 4C illustrates a circuit diagram to a third load according to some embodiments. FIG. 4D illustrates a circuit diagram to a fourth load according to some embodiments. Each of FIGS. 4A-4D illustrate the differential driver and a differential receiver, with circuit elements (e.g., resistors and op-amps) having the same values and in the same configuration. The only differences are in the lowpass filters, whose characteristic impedances change between and whose capacitances may change between the circuit diagrams as described above. The op-amp connections for the driver shown are symmetric between the individual traces of the differential signal pair. The values of the various elements in FIGS. 4A-4D, as well as circuit connections, are only one example of the M-LVDS circuit described herein.

In particular, FIG. 4A shows the circuit for the first load, which is closest to the M-LVDS driver. In the circuit of FIG. 4A, a differential driver on the left side of the figure and a differential receiver on the right side of the figure. The differential driver includes voltage source VG1, resistors R3, R4, R5, R6, R7 (all 1 kΩ), resistors R13, R14, R15, R16 (all 100 kΩ), and voltage-controlled voltage sources (op-amps) IOP1, IOP2. The positive input of op-amp IOP1 and the negative input of op-amp IOP2 are coupled to the voltage source VG1 and to the input voltage Vin respectively through resistor R3, R4. The positive input of op-amp IOP1 is further coupled to ground through resistor R13. The negative input of op-amp IOP2 is further coupled to ground through a series combination of resistors R6 and R15. The negative input of op-amp IOP1 is coupled to ground through resistor R7 and to the output of op-amp IOP1 through resistor R5. The output of op-amp IOP1 is coupled to ground through resistor R16. The positive input of op-amp IOP2 is coupled to ground through resistor R14. The negative input of op-amp IOP2 is coupled to the output of op-amp IOP2 through resistor R6. The output of op-amp IOP2 is coupled to ground through resistor R15.

The first single pole lowpass filter is between the differential driver and the differential receiver. The filter includes resistors R1 and R2 (both 64Ω) and capacitor C1 (5 pF) coupled between the resistors. Resistor R1 is coupled to the output of op-amp IOP1; resistor R2 is coupled to the output of op-amp IOP2. This filter has the lowest corner frequency among the four filters, set at approximately 249 MHz in one example to reduce the energy of the third harmonic of the 100 MHz signal.

The differential receiver includes resistor R8 (64Ω), resistors R9, R10, R11, R12 (all 100 kΩ), and a voltage-controlled voltage source (op-amp) IOP3. The positive input of op-amp IOP3 is coupled to resistor R1 through resistor R10 and to ground through resistor R9. The negative input of op-amp IOP3 is coupled to resistor R2 through resistor R11 and to the output of op-amp IOP3 through resistor R8. The output of op-amp IOP3, which provides the output to the circuit, is coupled to ground through resistor R12.

FIG. 4B depicts the circuit diagram for the second load. Similar to FIG. 4A, FIG. 4B shows a differential driver and receiver, but with different filter element values. In this case, resistors R1 and R2 are 32Ω rather than 64Ω; capacitor C1 is still 5 pF. This filter has a higher corner frequency of about 497 MHz, targeting the fifth harmonic of the 100 MHz signal.

FIG. 4C presents the circuit diagram for the third load. The filter in this diagram uses resistors R1, R2 (both 16Ω) and a smaller capacitor C1 (3 pF) than the filters of FIGS. 4A and 4B. This configuration results in an even higher corner frequency of approximately 1.66 GHz.

FIG. 4D shows the circuit diagram for the fourth load, which is the farthest from the M-LVDS driver among the filtered loads. The filter here includes resistors R1 and R2 (both 8Ω) and capacitor C1 (3 pF) having the same capacitance as FIG. 4C, resulting in the highest corner frequency of about 3.3 GHz.

In each of FIGS. 4A-4D, the differential driver and receiver sections remain consistent, with the same component values and configurations. The only differences lie in the lowpass filter sections, whose characteristic impedances and capacitances change to provide the desired filtering characteristics for each load position.

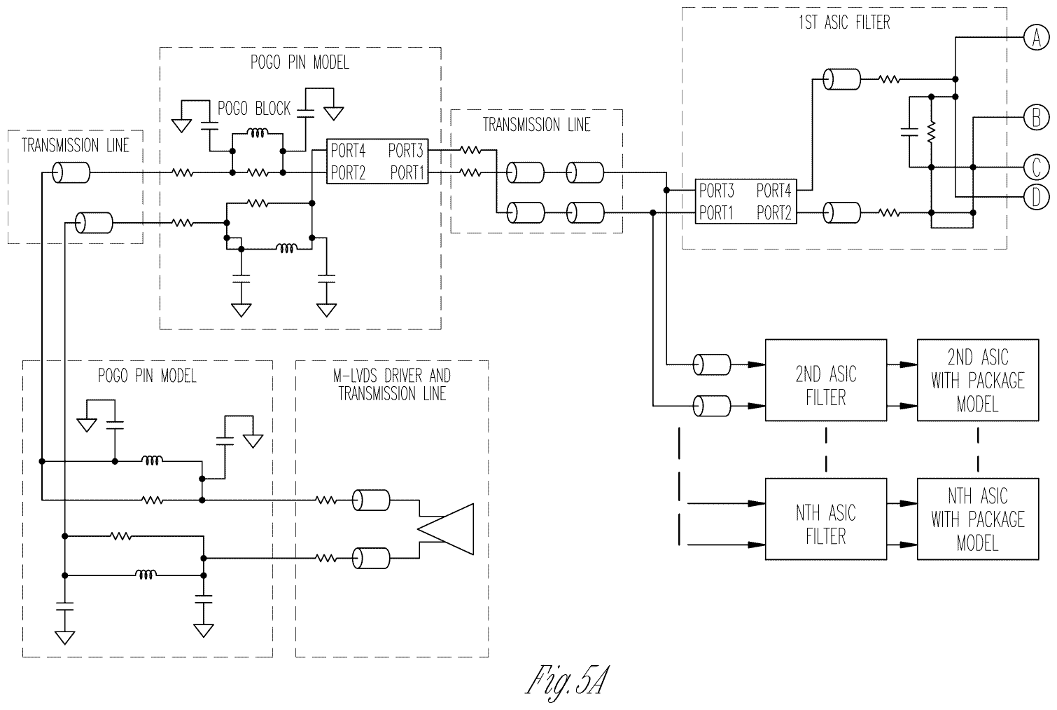

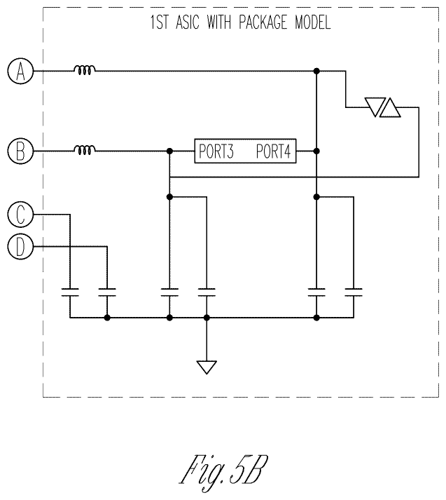

FIGS. 5A and 5B illustrate a comprehensive circuit diagram of the entire M-LVDS system with multiple loads. FIGS. 5A and 5B show the M-LVDS driver U30 on the left side, connected to a 2.8-inch 100Ω differential pair transmission line TL15, TL16. The signal then passes through a pogo block connector J17 before entering a 1.4-inch 100Ω differential pair section TL17, TL18. After this, the signal splits into two branches, each with a 63Ω differential characteristic impedance.

Each branch connects to multiple LVDS receivers (U1-U9 on one branch, U10-U18 on the other). The first four receivers on each branch (U1-U4 and U10-U13) have the single pole lowpass filters as described in FIGS. 4A-4D. The remaining receivers are connected directly to the transmission line without additional filtering.

At the end of each branch, there is a termination resistor (R14 and R16) to match the 63Ω differential characteristic impedance of the branch. This termination helps to minimize signal reflections and maintain signal integrity throughout the system.

FIGS. 5A and 5B also show additional components such as capacitors and resistors that may be used for signal conditioning or measurement purposes. The overall layout demonstrates how the embodiments herein enable multiple ASIC loads (up to 18 in this case) to be connected to a single M-LVDS channel while maintaining signal integrity and minimizing timing violations through the use of strategically placed and configured lowpass filters.

Simulations were made for 18 ASICs using the circuit elements described in the above figures (a 63Ω differential (with other CCAs of 100Ω)) both with and without lowpass filters. Results of a first simulation with no lowpass filters at the ASICs show variations in the peak-to-peak voltages in which the slow Vpp=579 mV (100 mV min) and the fast Vpp=1.03V (100 mV min) with a 1.27 ns skew between the first ASIC and the last ASIC on the branch. Results of a second simulation with lowpass filters only at the first four ASICs show variations in the peak-to-peak voltages in which the slow Vpp=579 mV (100 mV min) and the fast Vpp=776 mV (100 mV min) with a 0.936 ns skew between the first ASIC and the last ASIC on the branch. The skew reduction using the lowpass filters is about 25%. The skew is the maximum delay at the first load minus the minimum delay at the last load.

The embodiments herein avoid issues with other circuit arrangements such as complicated ring structures to transmit data, complicated non-symmetric PCB layer stacks, and the use of additional circuitry, such as feedback to determine the transmission line characteristic impedance and adjust the driver to match the impedance or power splitters for a large number of loads (e.g., 18+ as described herein). The routing and transmission line termination techniques described herein enable the use of an increased number of loads on a single high speed differential pair. While the routing techniques described herein are scalable to at least two branches, more severe characteristic impedance mismatch occurs at the branches when an increasing number of branches is used. Thus, if three or more branches are used, more complicated filters or other techniques may be used to reduce the increased characteristic impedance mismatch. Adding a single pole filter at each of the first set (e.g., 4) loads as above may also reduce the delay to match with other loads, reducing the skew in some cases by about 25%, which is significant for high-speed digital design because of the narrow clock period (any skew causes timing margin degradation). The filters are scaled to appear to the circuit like high impedance stubs to minimize transmission line effects, reducing the dynamic power by 40% and enabling lower implementation cost and shorter development cycles. The filters may also be scaled to higher order filters to further reduce the skew and to better optimize signal integrity if desired; in this design, only a single pole filter was used.

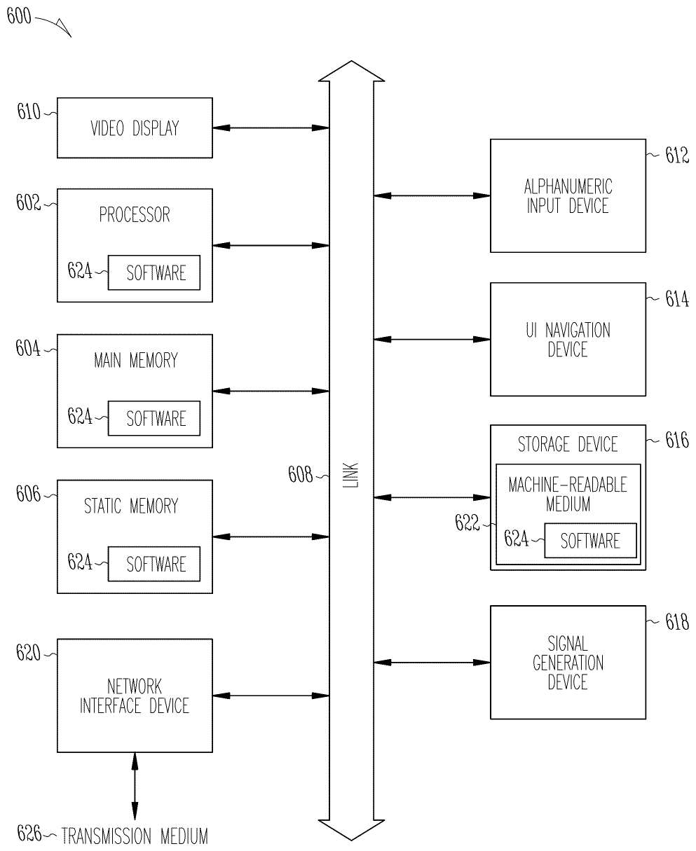

FIG. 6 illustrates a block diagram of an electronic device in accordance with some aspects. The electronic device 600 may be a device using the PCB described in the above figures and that is capable of executing instructions (sequential or otherwise) that specify actions to be taken by that device. Examples, as described herein, may include, or may operate on, logic or a number of components, modules, or mechanisms. Modules and components are tangible entities (e.g., hardware) capable of performing specified operations and may be configured or arranged in a certain manner. In an example, circuits may be arranged (e.g., internally or with respect to external entities such as other circuits) in a specified manner as a module. In an example, the whole or part of one or more computer systems (e.g., a standalone, client or server computer system) or one or more hardware processors may be configured by firmware or software (e.g., instructions, an application portion, or an application) as a module that operates to perform specified operations. In an example, the software may reside on a machine readable medium. In an example, the software, when executed by the underlying hardware of the module, causes the hardware to perform the specified operations.

Accordingly, the term “module” (and “component”) is understood to encompass a tangible entity, be that an entity that is physically constructed, specifically configured (e.g., hardwired), or temporarily (e.g., transitorily) configured (e.g., programmed) to operate in a specified manner or to perform part or all of any operation described herein. Considering examples in which modules are temporarily configured, each of the modules need not be instantiated at any one moment in time. For example, where the modules comprise a general-purpose hardware processor configured using software, the general-purpose hardware processor may be configured as respective different modules at different times. Software may accordingly configure a hardware processor, for example, to constitute a particular module at one instance of time and to constitute a different module at a different instance of time.

The electronic device 600 may include a hardware processor (or equivalently processing circuitry) 602 (e.g., a central processing unit (CPU), a GPU, a hardware processor core, or any combination thereof), a main memory 604 and a static memory 606, some or all of which may communicate with each other via an interlink (e.g., bus) 608. The main memory 604 may contain any or all of removable storage and non-removable storage, volatile memory or non-volatile memory. The electronic device 600 may further include a display unit 610 such as a video display, an alphanumeric input device 612 (e.g., a keyboard), and a user interface (UI) navigation device 614 (e.g., a mouse). In an example, the display unit 610, input device 612 and UI navigation device 614 may be a touch screen display. The electronic device 600 may additionally include a storage device (e.g., drive unit) 616, a signal generation device 618 (e.g., a speaker), a network interface device 620, and one or more sensors, such as a global positioning system (GPS) sensor, compass, accelerometer, or another sensor. The electronic device 600 may further include an output controller, such as a serial (e.g., universal serial bus (USB), parallel, or other wired or wireless (e.g., infrared (IR), near field communication (NFC), etc.) connection to communicate or control one or more peripheral devices (e.g., a printer, card reader, etc.).

The storage device 616 may include a non-transitory machine readable medium 622 (hereinafter simply referred to as machine readable medium) on which is stored one or more sets of data structures or instructions 624 (e.g., software) embodying or utilized by any one or more of the techniques or functions described herein. The non-transitory machine readable medium 622 is a tangible medium. The instructions 624 may also reside, completely or at least partially, within the main memory 604, within static memory 606, and/or within the hardware processor 602 during execution thereof by the electronic device 600. While the machine readable medium 622 is illustrated as a single medium, the term “machine readable medium” may include a single medium or multiple media (e.g., a centralized or distributed database, and/or associated caches and servers) configured to store the one or more instructions 624.

The term “machine readable medium” may include any medium that is capable of storing, encoding, or carrying instructions for execution by the electronic device 600 and that cause the electronic device 600 to perform any one or more of the techniques of the present disclosure, or that is capable of storing, encoding or carrying data structures used by or associated with such instructions. Non-limiting machine-readable medium examples may include solid-state memories, and optical and magnetic media. Specific examples of machine-readable media may include non-volatile memory, such as semiconductor memory devices (e.g., Electrically Programmable Read-Only Memory (EPROM), Electrically Erasable Programmable Read-Only Memory (EEPROM)) and flash memory devices; magnetic disks, such as internal hard disks and removable disks; magneto-optical disks; Random Access Memory (RAM); and CD-ROM and DVD-ROM disks.

The instructions 624 may further be transmitted or received over a communications network using a transmission medium 626 via the network interface device 620 utilizing any one of a number of wireless local area network (WLAN) transfer protocols (e.g., frame relay, internet protocol (IP), transmission control protocol (TCP), user datagram protocol (UDP), hypertext transfer protocol (HTTP), etc.). Example communication networks may include a local area network (LAN), a wide area network (WAN), a packet data network (e.g., the Internet), mobile telephone networks (e.g., cellular networks), IEEE 802.11 family of standards, and wireless data networks. In an example, the network interface device 620 may include one or more physical jacks (e.g., Ethernet, coaxial, or phone jacks) or one or more antennas to connect to the transmission medium 626.

Note that the term “circuitry” as used herein refers to, is part of, or includes hardware components such as an electronic circuit, a logic circuit, a processor (shared, dedicated, or group) and/or memory (shared, dedicated, or group), an Application Specific Integrated Circuit (ASIC), a field-programmable device (FPD) (e.g., a field-programmable gate array (FPGA), a programmable logic device (PLD), a complex PLD (CPLD), a high-capacity PLD (HCPLD), a structured ASIC, or a programmable SoC), digital signal processors (DSPs), etc., that are configured to provide the described functionality. In some embodiments, the circuitry may execute one or more software or firmware programs to provide at least some of the described functionality. The term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The term “processor circuitry” or “processor” as used herein thus refers to, is part of, or includes circuitry capable of sequentially and automatically carrying out a sequence of arithmetic or logical operations, or recording, storing, and/or transferring digital data. The term “processor circuitry” or “processor” may refer to one or more application processors, one or more baseband processors, a physical central processing unit (CPU), a single- or multi-core processor, and/or any other device capable of executing or otherwise operating computer-executable instructions, such as program code, software modules, and/or functional processes.

Any of the radio links described herein may operate according to any one or more of the following radio communication technologies and/or standards including but not limited to: a GSM radio communication technology, a GPRS radio communication technology, an Enhanced Data Rates for GSM Evolution (EDGE) radio communication technology, and/or a Third Generation Partnership Project (3GPP) radio communication technology.

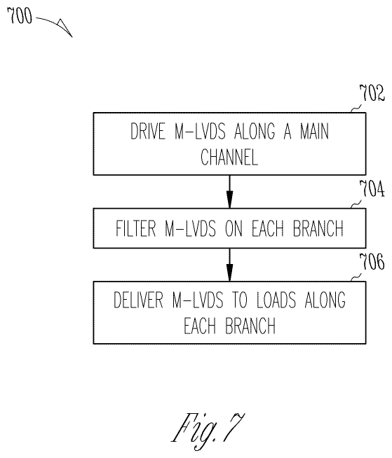

FIG. 7 illustrates a method of providing a differential signal in a PCB in accordance with some aspects. In some embodiments, the electronic device(s), network(s), system(s), chip(s) or component(s), or portions or implementations thereof may be configured to perform one or more processes, techniques, or methods as described herein, or portions thereof. Only some of the operations are shown in the process 700 of FIG. 7; other operations may be present but are not shown.

At operation 702, a M-LVDS is driven along a main channel. A M-LVDS driver in a CCA of a PCB is used to drive the differential signal. The main channel is split into branches at another CCA of the PCB each having a substantially identical differential impedance as the main channel.

At operation 704, the M-LVDS is filtered at on each branch by lowpass filters having different characteristics. The lowpass filters may be single pole or multi-pole lowpass filters.

At operation 706, the M-LVDS is delivered to loads on each of the branches. The M-LVDS is filtered before being delivered to a limited number of the loads. The loads may be ASICs. The filter characteristics are dependent on the propagation delay from the driver providing the M-LVDS and the load. The characteristics are varied among the filters to reduce energy of harmonics of the M-LVDS to slow down an edge rate of the M-LVDS and compensate for signal skew associated multiple loads on the main channel. The same number of loads and filters are provided on each branch.

### Examples

Example 1 is a multipoint low voltage differential signaling (M-LVDS) circuit comprising: a M-LVDS driver configured to provide a differential signal along a main channel; a plurality of loads configured to receive the differential signal, the main channel split into branches along which the loads are disposed; and a plurality of filters, each filter being a 1^{st} order or higher filter that is coupled between the M-LVDS driver and a different load of a subset of the loads along each branch such that fewer filters than loads are on each branch.

In Example 2, the subject matter of Example 1 includes, wherein the filters are configured differently at each load of the subset of the loads to compensate for a propagation delay between the M-LVDS driver and the load.

In Example 3, the subject matter of Example 2 includes, wherein each filter comprises a single pole lowpass filter.

In Example 4, the subject matter of Example 3 includes, wherein the filters within each branch have different corner frequencies.

In Example 5, the subject matter of Example 4 includes, wherein the corner frequencies increase with increasing distance from the M-LVDS driver.

In Example 6, the subject matter of Examples 4-5 includes, wherein within each branch: each filter comprises a resistance and capacitance that provide the corner frequency of the filter, each resistance is different and decreases with increasing distance from the M-LVDS driver, at least some of the capacitances decrease with increasing distance from the M-LVDS driver, and at least one of the capacitances is identical to at least one other of the capacitances.

In Example 7, the subject matter of Examples 2-6 includes, wherein the propagation delay is directly proportional to distance from the M-LVDS driver.

In Example 8, the subject matter of Examples 1-7 includes, wherein the filters are configured to reduce energy of harmonics of the differential signal impinging on the filters to slow down an edge rate of the differential signal and compensate for signal skew associated multiple loads on the main channel by providing different filter characteristics within each branch.

In Example 9, the subject matter of Examples 1-8 includes, wherein each branch contains an identical number of loads.

In Example 10, the subject matter of Examples 1-9 includes, wherein each subset contains an identical number of loads.

In Example 11, the subject matter of Examples 1-10 includes, wherein the branches have a substantially identical differential characteristic impedance as the main channel.

Example 12 is a printed circuit board (PCB) stack comprising: a multipoint low voltage differential signaling (M-LVDS) driver disposed on a first PCB and configured to provide a differential signal along a main channel; a plurality of application-specific integrated circuits (ASICs) configured to receive the differential signal, the plurality of ASICs disposed on a second PCB, the main channel split into branches along which the ASICs are disposed, the branches configured to have a substantially identical characteristic impedance as the main channel; and a plurality of filters coupled between the M-LVDS driver and the ASICs, the plurality of filters disposed on the second PCB, each filter coupled between the M-LVDS driver and a different ASIC of a subset of the ASICs along each branch such that fewer filters than ASICs are on each branch, each filter being a 1^{st} order or higher filter.

In Example 13, the subject matter of Example 12 includes, wherein the filters are configured differently at each ASIC of the subset of the ASICs to compensate for a propagation delay between the M-LVDS driver and the ASIC.

In Example 14, the subject matter of Example 13 includes, wherein each filter comprises a single pole lowpass filter.

In Example 15, the subject matter of Example 14 includes, wherein the filters within each branch have different corner frequencies.

In Example 16, the subject matter of Example 15 includes, wherein the corner frequencies increase with increasing distance from the M-LVDS driver.

In Example 17, the subject matter of Examples 15-16 includes, wherein within each branch: each filter comprises a resistance and capacitance that provide the corner frequency of the filter, each resistance is different and decreases with increasing distance from the M-LVDS driver, at least some of the capacitances decrease with increasing distance from the M-LVDS driver, and at least one of the capacitances is identical to at least one other of the capacitances.

In Example 18, the subject matter of Examples 12-17 includes, wherein the filters are configured to reduce energy of harmonics of the differential signal impinging on the filters to slow down an edge rate of the differential signal.

Example 19 is a method of providing a differential signal in a printed circuit board (PCB) stack, the method comprising: driving a multipoint low voltage differential signal from a first PCB along a main channel, the main channel split into branches having a substantially identical characteristic impedance as the main channel; and delivering the differential signal to a plurality of loads disposed along each of the branches on a second PCB, the differential signal filtered on the second PCB to prior to delivery of the differential signal to a subset of the loads along each branch.

In Example 20, the subject matter of Example 19 includes, wherein for each branch, filtering, using a 1^{st} order or higher filter, of the differential signal is configured to compensate for a propagation delay from a multipoint low voltage differential signaling (M-LVDS) driver providing the differential signal and the load and to reduce energy of harmonics of the differential signal to slow down an edge rate of the differential signal.

Example 21 is at least one machine-readable medium including instructions that, when executed by processing circuitry, cause the processing circuitry to perform operations to implement of any of Examples 1-20.

Example 22 is an apparatus comprising means to implement of any of Examples 1-20.

Example 23 is a system to implement of any of Examples 1-20.

Example 24 is a method to implement of any of Examples 1-20.

Although embodiments have been described with reference to specific example embodiments, it will be evident that various modifications and changes may be made to these embodiments without departing from the broader scope of the present disclosure. Accordingly, the specification and drawings are to be regarded in an illustrative rather than a restrictive sense. The accompanying drawings that form a part hereof show, by way of illustration, and not of limitation, specific embodiments in which the subject matter may be practiced. The embodiments illustrated are described in sufficient detail to enable those skilled in the art to practice the teachings disclosed herein. Other embodiments may be utilized and derived therefrom, such that structural and logical substitutions and changes may be made without departing from the scope of this disclosure. This Detailed Description, therefore, is not to be taken in a limiting sense, and the scope of various embodiments is defined only by the appended claims, along with the full range of equivalents to which such claims are entitled.

The subject matter may be referred to herein, individually and/or collectively, by the term “embodiment” merely for convenience and without intending to voluntarily limit the scope of this application to any single concept if more than one is in fact disclosed. Thus, although specific embodiments have been illustrated and described herein, it should be appreciated that any arrangement calculated to achieve the same purpose may be substituted for the specific embodiments shown. This disclosure is intended to cover any and all adaptations or variations of various embodiments. Combinations of the above embodiments, and other embodiments not specifically described herein, will be apparent to those of skill in the art upon reviewing the above description.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, UE, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects. For example, the term “a processor” configured to carry out specific operations includes both a single processor configured to carry out all of the operations as well as multiple processors individually configured to carry out some or all of the operations (which may overlap) such that the combination of processors carry out all of the operations. Note that the term “about x” and similar terms (e.g., substantially) as used herein may be understood to be within 10% of x or otherwise within a range known to one of skill in the art to be within tolerance of the quantity or quality described unless indicated otherwise.

The Abstract of the Disclosure is submitted with the understanding that it will not be used to interpret or limit the scope or meaning of the claims. In addition, in the foregoing Detailed Description, it may be seen that various features are grouped together in a single embodiment for the purpose of streamlining the disclosure. This method of disclosure is not to be interpreted as reflecting an intention that the claimed embodiments require more features than are expressly recited in each claim. Rather, as the following claims reflect, subject matter lies in less than all features of a single disclosed embodiment. Thus, the following claims are hereby incorporated into the Detailed Description, with each claim standing on its own as a separate embodiment.

1. A multipoint low voltage differential signaling (M-LVDS) circuit comprising:
a M-LVDS driver configured to provide a differential signal along a main channel;
a plurality of loads configured to receive the differential signal, the main channel split into branches along which the loads are disposed; and
a plurality of filters, each filter being a 1^{st} order or higher filter that is coupled between the M-LVDS driver and a different load of a subset of the loads along each branch such that fewer filters than loads are on each branch.

2. The M-LVDS circuit of claim 1, wherein the filters are configured differently at each load of the subset of the loads to compensate for a propagation delay between the M-LVDS driver and the load.

3. The M-LVDS circuit of claim 2, wherein each filter comprises a single pole lowpass filter.

4. The M-LVDS circuit of claim 3, wherein the filters within each branch have different corner frequencies.

5. The M-LVDS circuit of claim 4, wherein the corner frequencies increase with increasing distance from the M-LVDS driver.

6. The M-LVDS circuit of claim 4, wherein within each branch:
each filter comprises a resistance and capacitance that provide the corner frequency of the filter,
each resistance is different and decreases with increasing distance from the M-LVDS driver,
at least some of the capacitances decrease with increasing distance from the M-LVDS driver, and
at least one of the capacitances is identical to at least one other of the capacitances.

7. The M-LVDS circuit of claim 2, wherein the propagation delay is directly proportional to distance from the M-LVDS driver.

8. The M-LVDS circuit of claim 1, wherein the filters are configured to reduce energy of harmonics of the differential signal impinging on the filters to slow down an edge rate of the differential signal and compensate for signal skew associated multiple loads on the main channel by providing different filter characteristics within each branch.

9. The M-LVDS circuit of claim 1, wherein each branch contains an identical number of loads.

10. The M-LVDS circuit of claim 1, wherein each subset contains an identical number of loads.

11. The M-LVDS circuit of claim 1, wherein the branches have a substantially identical characteristic impedance as the main channel.

12. A printed circuit board (PCB) stack comprising:
a multipoint low voltage differential signaling (M-LVDS) driver disposed on a first PCB and configured to provide a differential signal along a main channel;
a plurality of application-specific integrated circuits (ASICs) configured to receive the differential signal, the plurality of ASICs disposed on a second PCB, the main channel split into branches along which the ASICs are disposed, the branches configured to have a substantially identical characteristic impedance as the main channel; and
a plurality of filters coupled between the M-LVDS driver and the ASICs, the plurality of filters disposed on the second PCB, each filter coupled between the M-LVDS driver and a different ASIC of a subset of the ASICs along each branch such that fewer filters than ASICs are on each branch, each filter being a 1^{st} order or higher filter.

13. The PCB stack of claim 12, wherein the filters are configured differently at each ASIC of the subset of the ASICs to compensate for a propagation delay between the M-LVDS driver and the ASIC.

14. The PCB stack of claim 13, wherein each filter comprises a single pole lowpass filter.

15. The PCB stack of claim 14, wherein the filters within each branch have different corner frequencies.

16. The PCB stack of claim 15, wherein the corner frequencies increase with increasing distance from the M-LVDS driver.

17. The PCB stack of claim 15, wherein within each branch:
each filter comprises a resistance and capacitance that provide the corner frequency of the filter,
each resistance is different and decreases with increasing distance from the M-LVDS driver,
at least some of the capacitances decrease with increasing distance from the M-LVDS driver, and
at least one of the capacitances is identical to at least one other of the capacitances.

18. The PCB stack of claim 12, wherein the filters are configured to reduce energy of harmonics of the differential signal impinging on the filters to slow down an edge rate of the differential signal.

19. A method of providing a differential signal in a printed circuit board (PCB) stack, the method comprising:
driving a multipoint low voltage differential signal from a first PCB along a main channel, the main channel split into branches having a substantially identical characteristic impedance as the main channel; and
delivering the differential signal to a plurality of loads disposed along each of the branches on a second PCB, the differential signal filtered on the second PCB to prior to delivery of the differential signal to a subset of the loads along each branch.

20. The method of claim 19, wherein for each branch, filtering, using a 1^{st} order or higher filter, of the differential signal is configured to compensate for a propagation delay from a multipoint low voltage differential signaling (M-LVDS) driver providing the differential signal and the load and to reduce energy of harmonics of the differential signal to slow down an edge rate of the differential signal.
